(19) United States
(12) Patent Application Publication
(10) Pub. No.: US 2013/0113347 A1
(43) Pub. Date: May 9, 2013

(54) LOCKING MECHANISM WITH EASY ASSEMBLY AND ELECTRONIC DEVICE THEREWITH

(71) Applicants: Zhong-hui Mao, New Taipei City (TW); Te-Hsiung Hsieh, New Taipei City (TW); Zhang-Rong Jin, New Taipei City (TW)

(72) Inventors: Zhong-hui Mao, New Taipei City (TW); Te-Hsiung Hsieh, New Taipei City (TW); Zhang-Rong Jin, New Taipei City (TW)

(21) Appl. No.: 13/602,305

(22) Filed: Sep. 3, 2012

(30) Foreign Application Priority Data
Nov. 3, 2011 (CN) 201120432168.1

(51) Int. Cl. H05K 5/03; E05C 5/02

(52) U.S. Cl. 312/223.1; 292/57

(57) ABSTRACT

A locking mechanism includes a lock for passing through an opening of a housing. The lock includes a lock head, a cover whereon a slot is formed, a constraining portion, and a platform structure for contacting against a fastening portion of the housing as the cover passes through the opening. The locking mechanism further includes a tongue piece installed on a side of the cover and rotating with the lock head synchronously. The tongue piece includes a latching portion for latching inside an indentation of a door as the tongue piece rotates to a latching position, and a stopping portion for contacting against an end of the constraining portion as the tongue piece rotates to the latching position. The locking mechanism further includes a jump ring for engaging inside the slot on the cover so as to fix the lock inside the housing.

### BACKGROUND OF THE INVENTION

1. Field of the Invention

The present invention relates to provide a locking mechanism and a related electronic device, and more specifically to a locking mechanism with easy assembly and a related electronic device therewith.

2. Description of the Prior Art

In order to ensure security of instruments and data stored in electronic devices and storage devices, it is needed to design a lock to prevent the instruments from being opened, erroneously operated or stolen. However, for meeting with design of a door of a personal storage device with a small size, it is inconvenient to assemble locking tools within a narrow installing space. The conventional lock is often installed by screws. In addition, as there is limited installing space inside the instrument, that is there is no sufficient space for disposing a screwing structure and for operating a screwing tool, such as a wrench, a pliers or a screwdriver, it results in difficulty in assembling the lock.

### SUMMARY OF THE INVENTION

The present invention is to provide a locking mechanism with easy assembly and a related electronic device to solve above problems.

According to the disclosure, a locking mechanism includes a lock for passing through an opening of a housing. The lock includes a lock head, and a cover for covering the lock head. A slot is formed on the cover. The lock further includes a constraining portion disposed on a side of the cover, and a platform structure disposed on the cover, for contacting against a fastening portion of the housing as the cover passes through the opening. The locking mechanism further includes a tongue piece installed on the side of the cover and rotating with the lock head synchronously. The tongue piece includes a latching portion for latching inside an indentation of a door as the tongue piece rotates to a latching position, so as to latch the door on the housing. The tongue piece further includes a stopping portion for contacting against an end of the constraining portion as the tongue piece rotates to the latching position. The locking mechanism further includes a jump ring for engaging inside the slot on the cover so as to fix the lock inside the housing.

According to the disclosure, the constraining portion is an arc protruding rib.

According to the disclosure, a locking hole is disposed on the tongue piece, and the locking mechanism further includes a locking component passing through the locking hole and fixing in the lock head.

According to the disclosure, the locking hole of the tongue piece is a strip hole.

According to the disclosure, the stopping portion includes two stopping blocks for respectively contacting against two ends of the constraining portion when the tongue piece rotates to different positions.

According to the disclosure, the jump ring includes a horseshoe buckle for buckling the slot, and a handle portion extended and bent from an end of the horseshoe buckle.

According to the disclosure, the jump ring includes at least one protrusion disposed at an inner side of the horseshoe buckle and for preventing the horseshoe buckle from separating from the slot.

According to the disclosure, the horseshoe buckle is a flexible arc structure, one side of the horseshoe buckle contacts against the fastening portion, and the other side of the horseshoe buckle contacts against a side wall of the slot.

According to the disclosure, an electronic device includes a housing whereon an opening and a fastening portion are disposed, a door connected to the housing. An indentation is formed on the door. The electronic device further includes a locking mechanism for locking the door on the housing. The locking mechanism includes a lock for passing through the opening of the housing. The lock includes a lock head, a cover for covering the lock head. A slot is formed on the cover. The lock further includes a constraining portion disposed on a side of the cover, and a platform structure disposed on the cover, for contacting against the fastening portion of the housing as the cover passes through the opening. The locking mechanism further includes a tongue piece installed on the side of the cover and rotating with the lock head synchronously. The tongue piece includes a latching portion for latching inside the indentation of the door as the tongue piece rotates to a latching position, so as to latch the door on the housing. The tongue piece further includes a stopping portion as the tongue piece rotates to the latching position. The locking mechanism further includes a jump ring for engaging inside the slot on the cover so as to fix the lock inside the housing.

The locking mechanism of the present invention is assembled without using any screw. The locking mechanism of the present invention does not occupy much mechanical space and has advantages of convenient installation, easy manufacture, cost reduction, and assembly without using any tool. Therefore, the present invention provides the locking mechanism with easy assembly.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an electronic device according to an embodiment of the present invention.

FIG. 2 is an internal structural diagram of a housing according to the embodiment of the present invention.

FIG. 3 to FIG. 5 are assembly diagrams of a locking mechanism according to the embodiment of the present invention.

FIG. 6 is a diagram of a lock according to the embodiment of the present invention.

FIG. 7 and FIG. 8 are respectively an assembly diagram and an exploded diagram of a lock and a tongue piece according to the embodiment of the present invention.

FIG. 9 is a diagram of a jump ring according to the embodiment of the present invention.

FIG. 10 is a diagram of the jump ring engaging with the lock according to the embodiment of the present invention.

FIG. 11 is a side view of the lock mechanism installing on an inner side of the housing according to the embodiment of the present invention.

FIG. 12 to FIG. 14 are diagrams of the tongue piece and a door in different positions according to the embodiment of the present invention.

### DETAILED DESCRIPTION

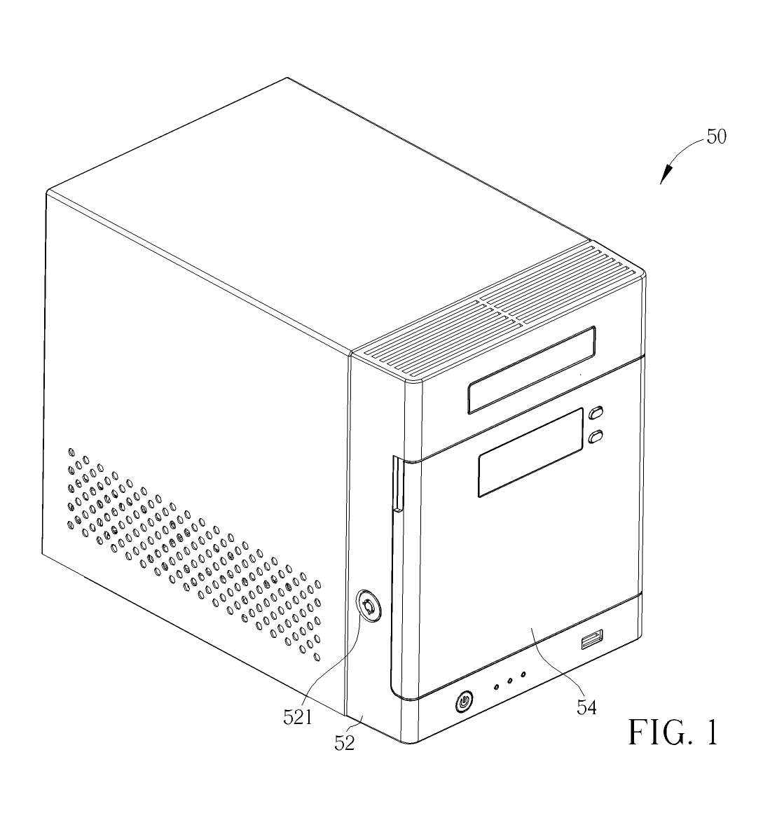

Please refer to FIG. 1. FIG. 1 is a diagram of an electronic device 50 according to an embodiment of the present invention. The electronic device 50 can be a computer host or a storage device and so on. The electronic device 50 includes a housing 52 whereon an opening 521 is disposed, and the housing 52 is used for covering internal components of the electronic device 50. The electronic device 50 further includes a door 54 connected to the housing 52. For example, the door 54 can be pivotally connected to the housing 52 and for covering the housing 52 by rotation. A plurality of containing slots can be disposed on the housing 52 for users to draw out a removable storage module, and the door 54 is to cover the plurality of containing slots. In addition, the electronic device 50 further includes a locking mechanism 56 for locking the door 54 on the housing 52.

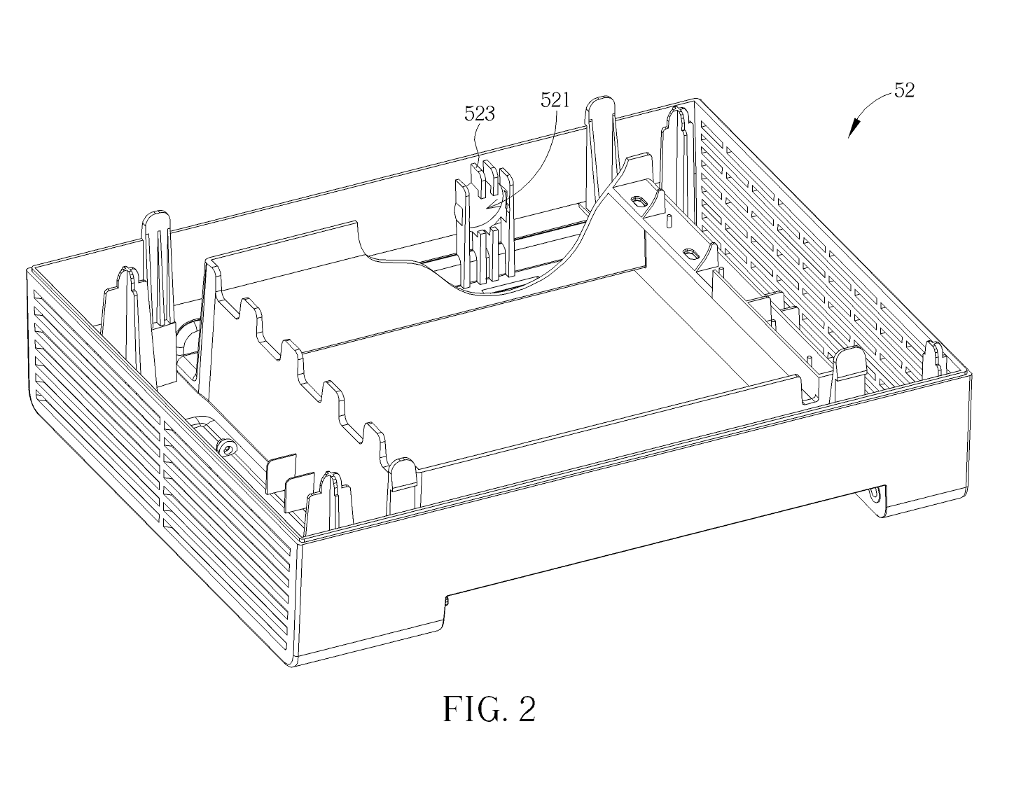

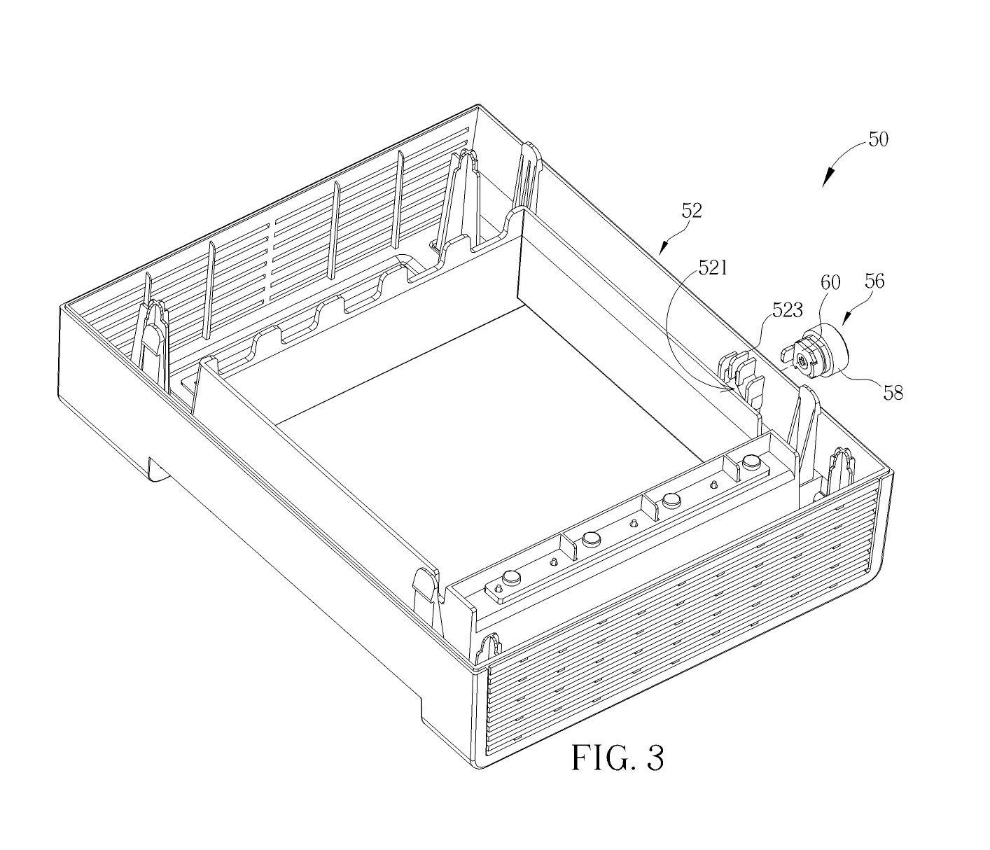

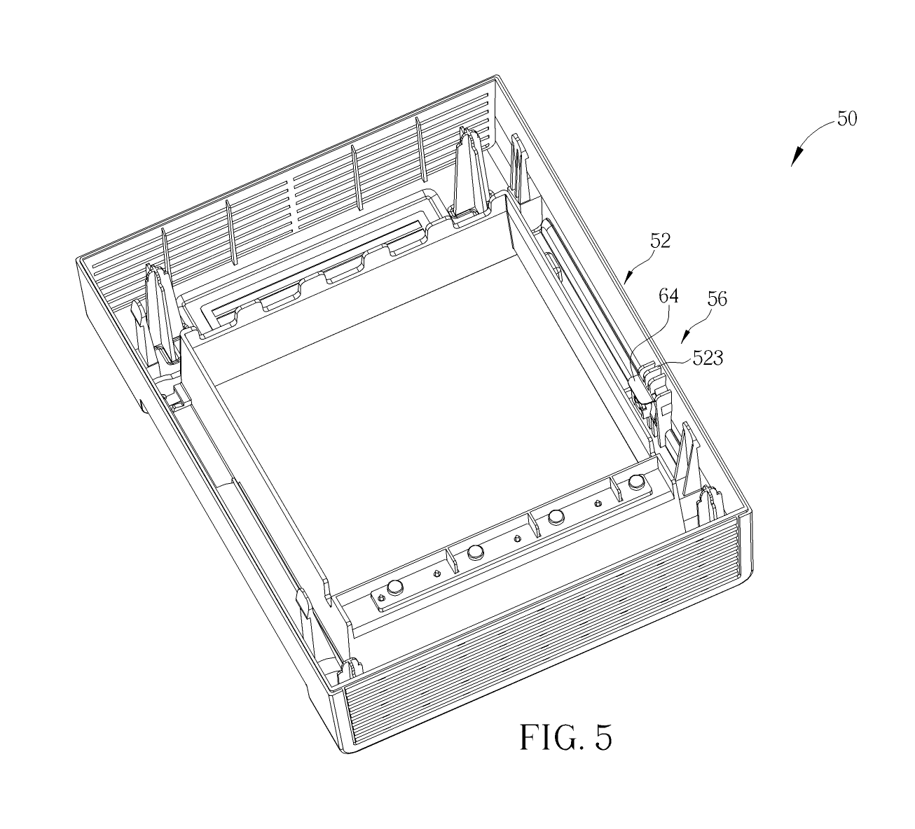

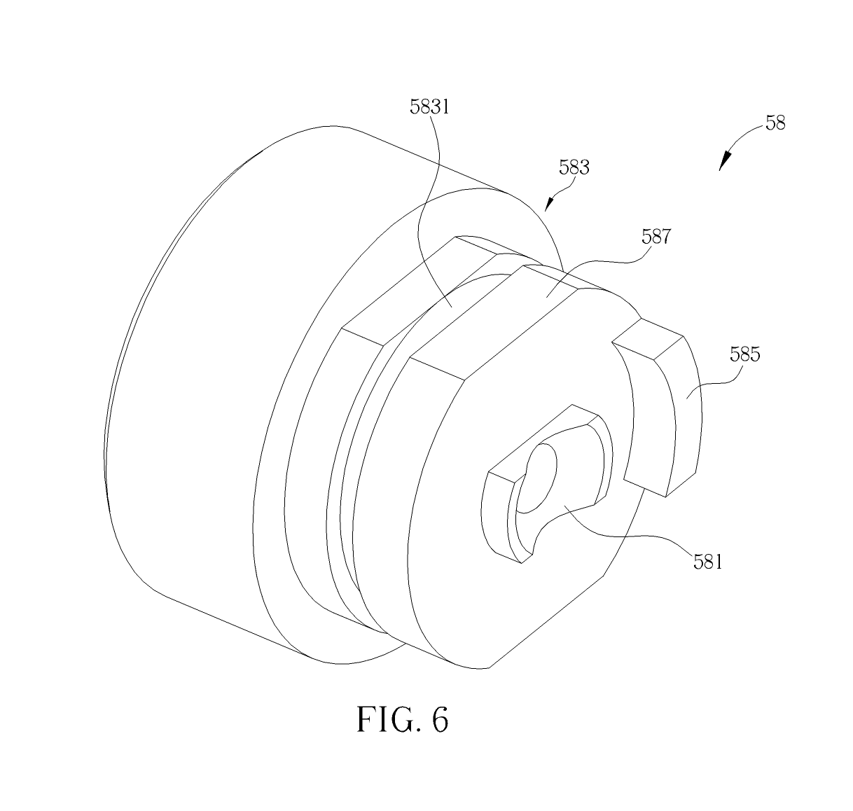

Please refer to FIG. 2 to FIG. 5. FIG. 2 is an internal structural diagram of the housing 52 according to the embodiment of the present invention. FIG. 3 to FIG. 5 are assembly diagrams of the locking mechanism 56 according to the embodiment of the present invention. A fastening portion 523 is disposed at an inner side of the housing 52 and can be composed of a plurality of ribs. In addition, the locking mechanism 56 includes a lock 58 for passing through the opening 521 of the housing 52. Please refer to FIG. 6. FIG. 6 is a diagram of the lock 58 according to the embodiment of the present invention. The lock 58 includes a lock head 581, a cover 583, a constraining portion 585 and a platform structure 587. The cover 583 is for covering the lock head 581, and a slot 5831 is formed on the cover 583. The constraining portion 585 is disposed on a side of the cover 583, and the constraining portion 585 can be an arc protruding ribs. The platform structure 587 is disposed on the cover 583, for contacting against the fastening portion 523 of the housing 52 as the cover 583 passes through the opening 521 of the housing 52, so that the lock 58 is engaged inside the opening 521 and with the fastening portion 523 tightly, resulting in constraining the cover 583 from rotating with the lock head 581 synchronously. The platform structure 587 of the cover 583 can be composed of a plurality of platforms.

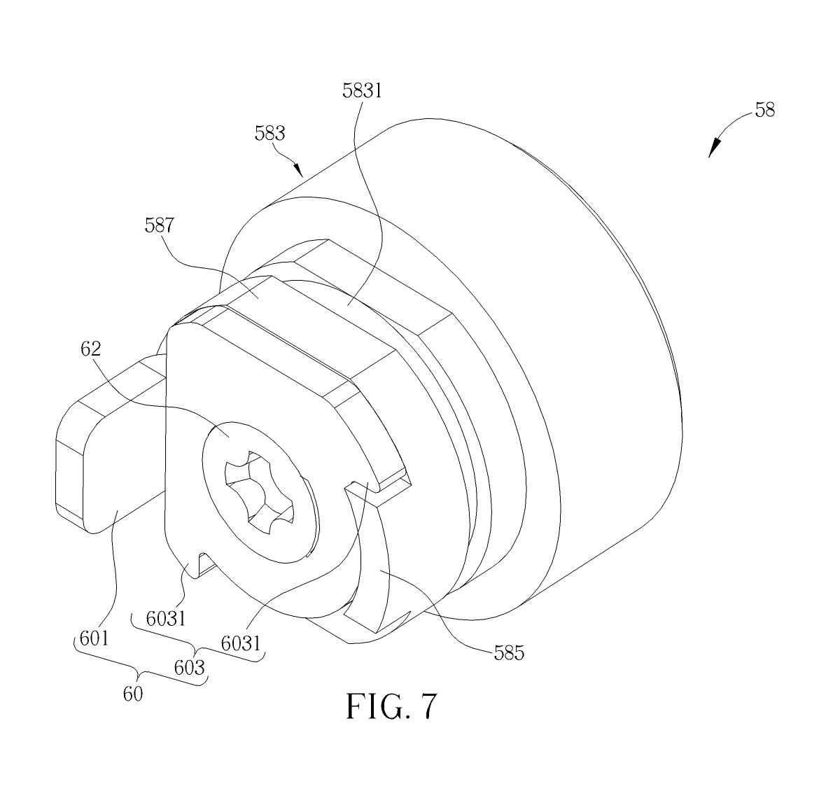

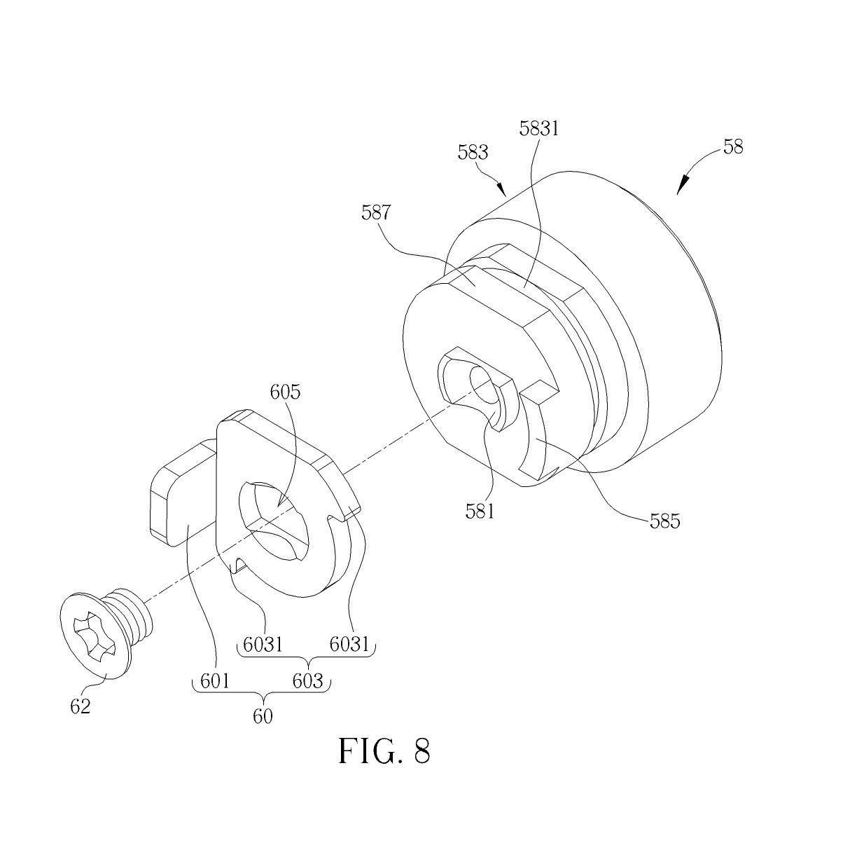

Moreover, the locking mechanism 56 further includes a tongue piece 60 installed on the side of the cover 583 and rotating with the lock head 581 synchronously. Please refer to FIG. 7 and FIG. 8. FIG. 7 and FIG. 8 are respectively an assembly diagram and an exploded diagram of the lock 58 and the tongue piece 60 according to the embodiment of the present invention. The tongue piece 60 includes a latching portion 601 for latching the door 54 on the housing 52. The tongue piece 60 further includes a stopping portion 603 for rotating to contact against an end of the constraining portion 585. In this embodiment, the stopping portion 603 includes two stopping blocks 6031 for respectively contacting against two ends of the constraining portion 585 when the tongue piece 60 rotates to different positions. Amounts and positions of the stopping blocks 6031 are not limited to this embodiment, and it depends on practical design demand. Besides, a locking hole 605 is disposed on the tongue piece 60, and the locking mechanism 56 further includes a locking component 62 passing through the locking hole 605 of the tongue piece 60 and fixing in the lock head 581, so that the tongue piece 60 and the lock head 581 can rotate synchronously. The locking component 62 can be a screw and the locking hole 605 of the tongue piece 60 can be a strip hole, so as to achieve better synchronous rotation.

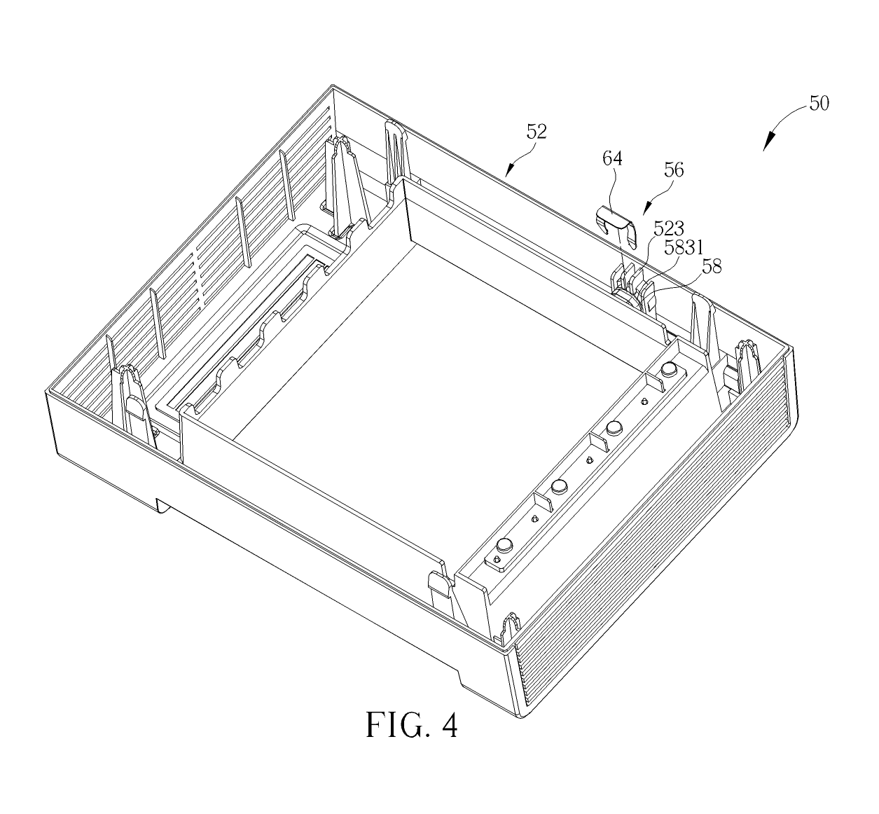

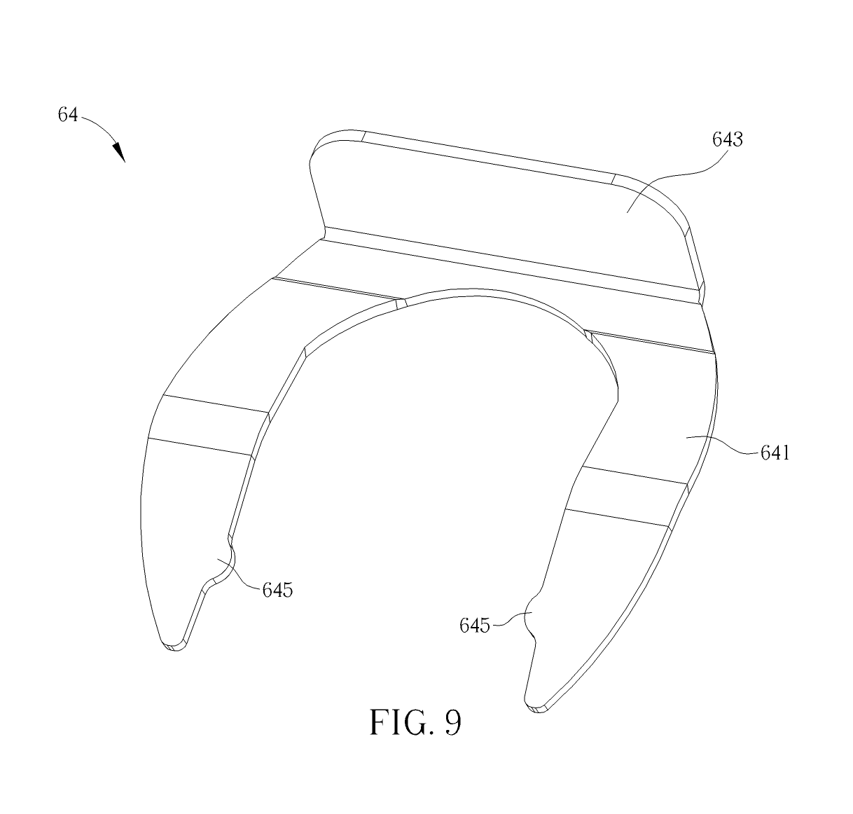

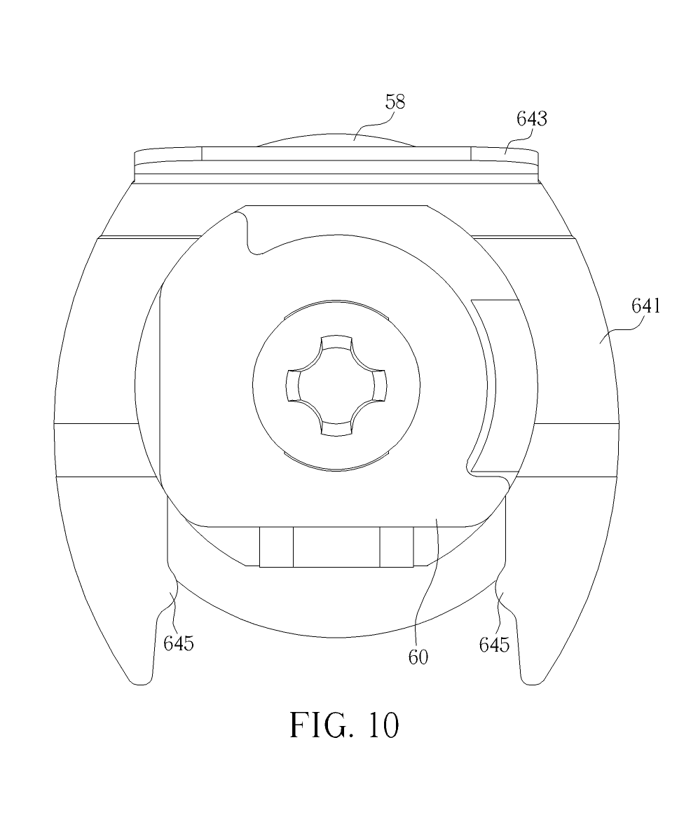

The locking mechanism 56 further includes a jump ring 64 for engaging inside the slot 5831 on the cover 583 of the lock 58 for fixing the lock 58 inside the housing 52. Please refer to FIG. 4, FIG. 9 and FIG. 10. FIG. 9 is a diagram of the jump ring 64 according to the embodiment of the present invention. FIG. 10 is a diagram of the jump ring 64 engaging with the lock 58 according to the embodiment of the present invention. The jump ring 64 includes a horseshoe buckle 641 and a handle portion 643. The flexible horseshoe buckle 641 is for buckling the slot 5831. The handle portion 643 is extended and bent from an end of the horseshoe buckle 641, which means a bending direction is substantially vertical to the installing direction of the handle portion 643, so as to facilitate users to buckle the jump ring 64 inside the slot 5831 or draw out the jump ring 64 from the slot 5831. In addition, the jump ring 64 further includes at least one protrusion 645 disposed at an inner side of the horseshoe buckle 641 and for preventing the horseshoe buckle 641 from separating from the slot 5831. In this embodiment, the jump ring 64 includes two protrusions 645 at two ends of the horseshoe buckle 641 to be stopped by the cover 583 of the lock 58 when the horseshoe buckle 641 is about to separate from the slot 5831, so as to ensure that the jump ring 64 can tightly engage inside the slot 5831 of the lock 58. The horseshoe buckle 641, the handle portion 643 and protrusion 645 of the jump ring 64 can be monolithically integrated.

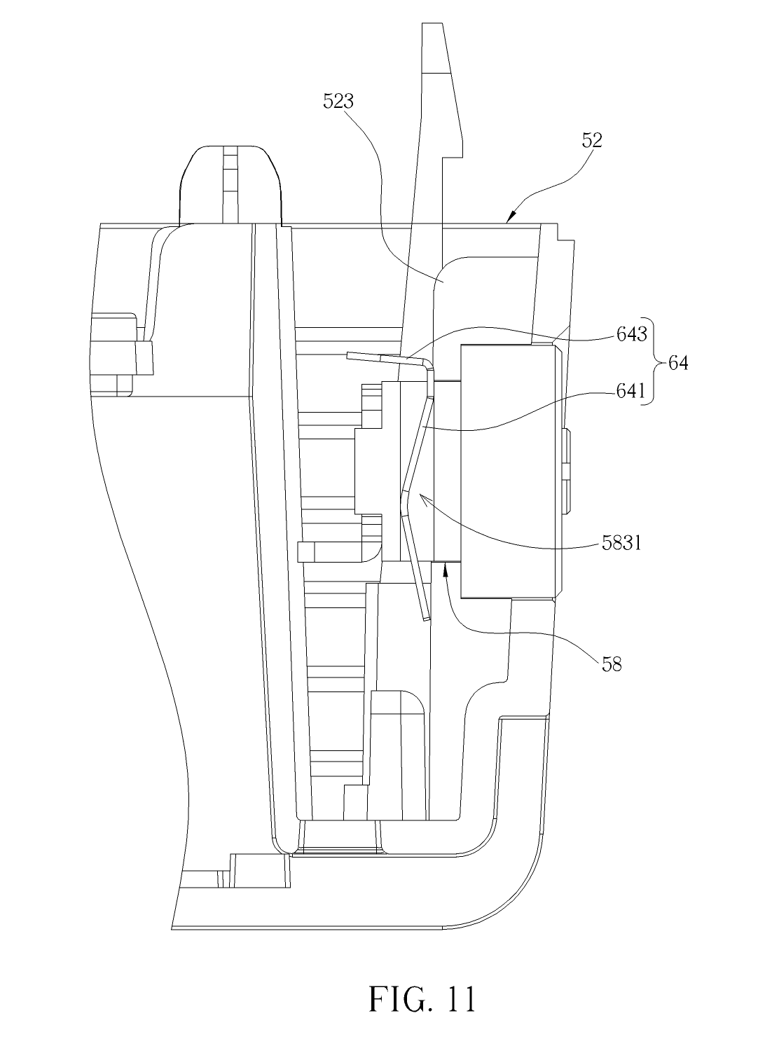

Please refer to FIG. 11. FIG. 11 is a side view of the lock mechanism 56 installing on the inner side of the housing 52 according to the embodiment of the present invention. The horseshoe buckle 641 of the jump ring 64 can be a flexible arc structure, as a result, when the lock 58 is installed inside the housing 52 and the jump ring 64 is engaged with the lock 58, a side of the horseshoe buckle 641 can tightly contact against the fastening portion 523 of the housing 52 and the other side of the horseshoe buckle 641 can tightly contact against the slot 5831 of the lock 58, so as to achieve axial constraint and to fix the lock 58 on the inner side of the housing 52.

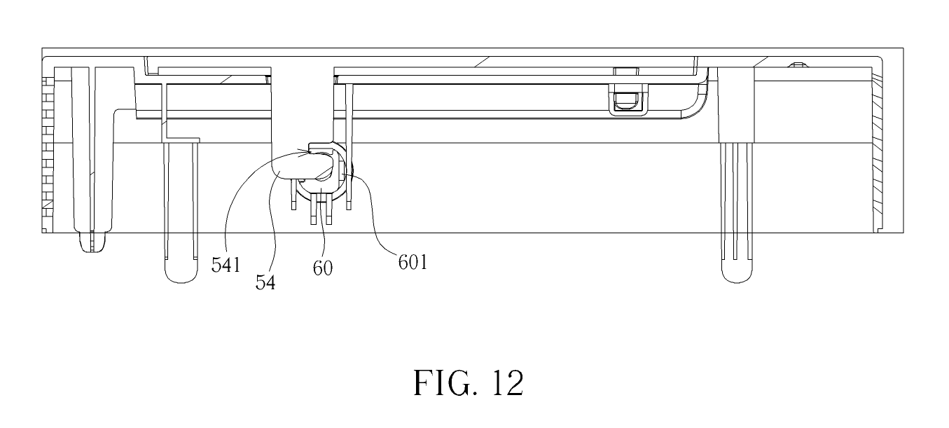

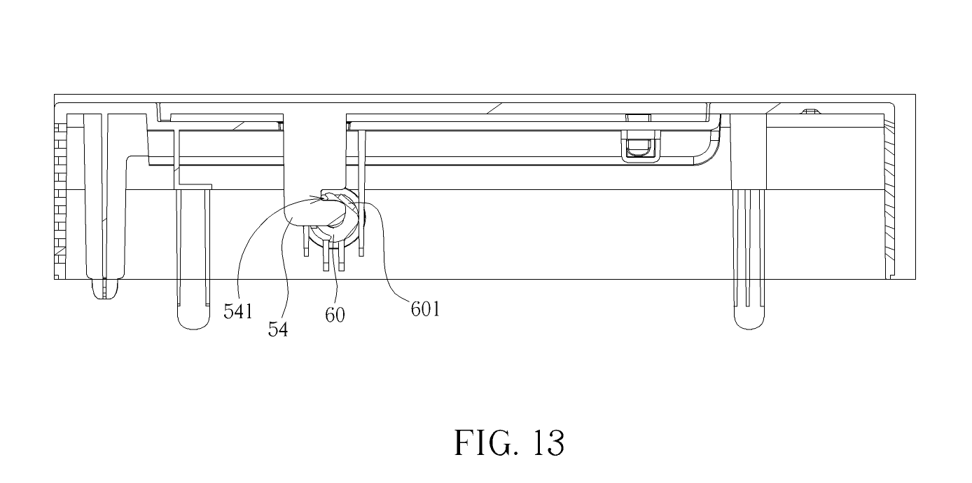

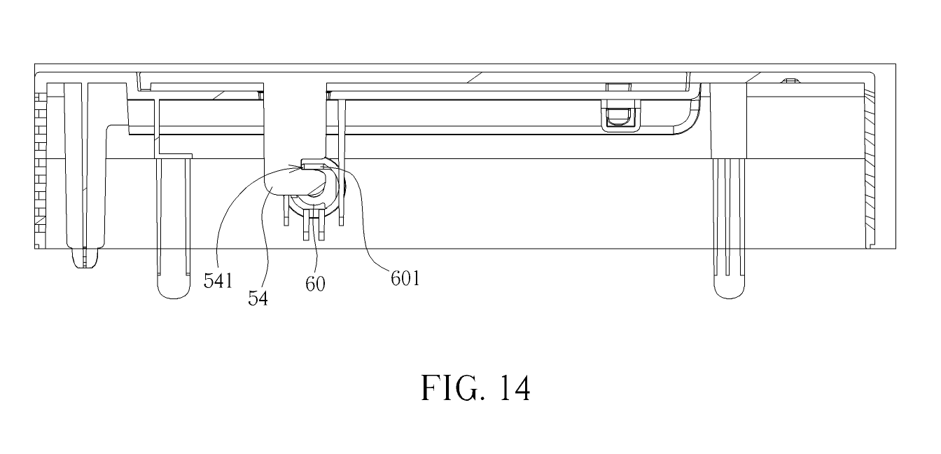

Please refer to FIG. 12 to FIG. 14. FIG. 12 to FIG. 14 are diagrams of the tongue piece 60 and the door 54 indifferent positions according to the embodiment of the present invention. Users can insert a key into the lock head 581 of the lock 58 and rotate the lock head 581 so as to rotate the tongue piece 60 synchronously. For example, the tongue piece 60 is at an initial position as shown in FIG. 12, and at that time, one of the stopping portions 6031 in FIG. 7 is to stop an end of the constraining portion 585. For latching the door 54 on the housing 52, the key is utilized to rotate the lock head 581 so as to rotate the tongue piece 60 counterclockwise from a position in FIG. 13 to a latching position in FIG. 14. An indentation 541 is formed on the door 54. As the tongue piece 60 rotates to the latching position as shown in FIG. 14, the latching portion 601 of the tongue piece 60 is engaged with the indentation 541 of the door 54 so as to latch the door 54 on the housing 52. On the contrary, for unlocking the door 54, the key is utilized to rotate the lock head 581, so as to rotate the tongue piece 60 from the position in FIG. 14 to the position in FIG. 12, which means performing reverse procedure of above actions, and therefore the detail description is omitted herein.

In contrast to the prior art, the locking mechanism of the present invention is assembled without using any screw. The locking mechanism of the present invention does not occupy much mechanical space and has advantages of convenient installation, easy manufacture, cost reduction, and assembly without using any tool. Therefore, the present invention provides the locking mechanism with easy assembly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A locking mechanism comprising:
a lock for passing through an opening of a housing, the lock comprising:
a lock head;
a cover for covering the lock head, a slot being formed on the cover;
a constraining portion disposed on a side of the cover; and
a platform structure disposed on the cover, for contacting against a fastening portion of the housing as the cover passes through the opening;
a tongue piece installed on the side of the cover and rotating with the lock head synchronously, the tongue piece comprising:
a latching portion for latching inside an indentation of a door as the tongue piece rotates to a latching position, so as to latch the door on the housing; and
a stopping portion for contacting against an end of the constraining portion as the tongue piece rotates to the latching position; and
a jump ring for engaging inside the slot on the cover so as to fix the lock inside the housing.

2. The locking mechanism of claim 1, wherein the constraining portion is an arc protruding rib.

3. The locking mechanism of claim 2, wherein the stopping portion comprises two stopping blocks for respectively contacting against two ends of the constraining portion when the tongue piece rotates to different positions.

4. The locking mechanism of claim 1, wherein a locking hole is disposed on the tongue piece, and the locking mechanism further comprises a locking component passing through the locking hole and fixing in the lock head.

5. The locking mechanism of claim 4, wherein the locking hole of the tongue piece is a strip hole.

6. The locking mechanism of claim 1, wherein the stopping portion comprises two stopping blocks for respectively contacting against two ends of the constraining portion when the tongue piece rotates to different positions.

7. The locking mechanism of claim 1, wherein the jump ring comprises:
a horseshoe buckle for buckling the slot; and
a handle portion extended and bent from an end of the horseshoe buckle.

8. The locking mechanism of claim 7, wherein the jump ring further comprises at least one protrusion disposed at an inner side of the horseshoe buckle and for preventing the horseshoe buckle from separating from the slot.

9. The locking mechanism of claim 8, wherein the horseshoe buckle is a flexible arc structure, one side of the horseshoe buckle contacts against the fastening portion, and the other side of the horseshoe buckle contacts against a side wall of the slot.

10. The locking mechanism of claim 7, wherein the horseshoe buckle is a flexible arc structure, one side of the horseshoe buckle contacts against the fastening portion, and the other side of the horseshoe buckle contacts against a side wall of the slot.

11. An electronic device comprising:
a housing whereon an opening and a fastening portion are disposed;
a door connected to the housing, an indentation being formed on the door; and
a locking mechanism for locking the door on the housing, the locking mechanism comprising:
a lock for passing through the opening of the housing, the lock comprising:
a lock head;
a cover for covering the lock head, a slot being formed on the cover;
a constraining portion disposed on a side of the cover; and
a platform structure disposed on the cover, for contacting against the fastening portion of the housing as the cover passes through the opening;
a tongue piece installed on the side of the cover and rotating with the lock head synchronously, the tongue piece comprising:
a latching portion for latching inside the indentation of the door as the tongue piece rotates to a latching position, so as to latch the door on the housing; and
a stopping portion as the tongue piece rotates to the latching position; and
a jump ring for engaging inside the slot on the cover so as to fix the lock inside the housing.

12. The electronic device of claim 11, wherein the constraining portion is an arc protruding rib.

13. The electronic device of claim 12, wherein the stopping portion comprises two stopping blocks for respectively contacting against two ends of the constraining portion when the tongue piece rotates to different positions.

14. The electronic device of claim 11, wherein a locking hole is disposed on the tongue piece, and the locking mechanism further comprises a locking component passing through the locking hole and fixing in the lock head.

15. The electronic device of claim 14, wherein the locking hole of the tongue piece is a strip hole.

16. The electronic device of claim 11, wherein the stopping portion comprises two stopping blocks for respectively contacting against two ends of the constraining portion when the tongue piece rotates to different positions.

17. The electronic device of claim 11, wherein the jump ring comprises:
a horseshoe buckle for buckling the slot; and
a handle portion extended and bent from an end of the horseshoe buckle.

18. The electronic device of claim 17, wherein the jump ring further comprises at least one protrusion disposed at an inner side of the horseshoe buckle and for preventing the horseshoe buckle from separating from the slot.

19. The electronic device of claim 18, wherein the horseshoe buckle is a flexible arc structure, one side of the horseshoe buckle contacts against the fastening portion, and the other side of the horseshoe buckle contacts against a side wall of the slot.

20. The electronic device of claim 17, wherein the horseshoe buckle is a flexible arc structure, one side of the horseshoe buckle contacts against the fastening portion, and the other side of the horseshoe buckle contacts against a side wall of the slot.
